(19) United States
(12) Patent Application Publication
(10) Pub. No.: US 2002/0118050 A1
(43) Pub. Date: Aug. 29, 2002

(54) Frequency doubler

(76) Inventor: Chris Grondahl, Chandler, AZ (US)

Correspondence Address: SNELL & WILMER, ONE ARIZONA CENTER, 400 EAST VAN BUREN, PHOENIX, AZ, 850040001

(21) Appl. No.: 09/792,509

(22) Filed: Feb. 23, 2001

(51) Int. Cl. H03B 19/00

(52) U.S. Cl. 327/122

(57) ABSTRACT

The invention provides a frequency doubler which uses an input tuning circuit configured to provide a low-pass frequency response and an input circuit configured to provide a high pass frequency response, where each tuning circuit drives a nonlinear device. The two nonlinear devices are fed 180 degrees out of phase, such that the even harmonics produced by the two non-linear devices are in phase while the odd harmonics produced by the non-linear devices are out of phase. The signals from the non-linear devices are combined into a single node producing a signal with a frequency that is twice the input frequency of the input signal.

### FIELD OF THE INVENTION

The invention relates generally to frequency multipliers and, in particular, to a frequency doubler.

### BACKGROUND OF THE INVENTION

In general, a frequency multiplier is a harmonic conversion transducer for producing an output signal at a frequency that is an integral multiple of the fundamental frequency of the input signal. Where a frequency multiplier is designed to increase the input frequency by a multiple of two the multiplier is termed a frequency doubler. Frequency multipliers, such as doublers, desirably produce an output signal that is rich in second harmonic of the fundamental frequency of the input signal.

One method of designing a frequency doubler uses a push-push multiplier circuit. In a push-push multiplier circuit, the input signal is used to generate two signals which are 180 degrees out of phase. Preferably, the resulting two signals are well balanced both in amplitude and phase, so that frequency multiplication can take place with minimal distortion. As used herein, the term “balanced” shall have the same meaning as that recognized in the art. That is, signals that are balanced for push-push operation are substantially equal with respect to power and amplitude, but have a phase difference of about 180 degrees.

Common push-push circuitry arrangements typically use a power-splitter to generate the two balanced signals. Conventional power splitters may typically include distributed element hybrid splitters or lumped element hybrid splitters. While both of the aforementioned splitters are effective for generating relatively balanced signals, each have a size constraint and are often not suitable in applications where miniaturization of components is desired (e.g., mobile receiver technology). For example, while the typical distributed element hybrid splitter effectively splits an input signal into two nearly identical signals that are substantially 180 degrees out of phase, the distributed element hybrid splitter is relatively large in comparison to the remaining doubler circuitry. Similarly, since lumped element hybrid splitters typically use circuitry elements, such as capacitors and inductors, to achieve balanced splitting of signals with a 180 degree phase difference, the lumped element hybrid splitter is also relatively large in comparison with the remaining doubler circuitry. Therefore, because of their relative size, where conventional power splitters are used in circuitry wherein miniaturization is desired, the cost of such circuitry is substantially affected.

In order to meet the requirements of cost restraints and system miniaturization, the conventional power splitter may desirably be incorporated onto a single integrated circuit (IC). That is, it is desirable to be able to incorporate the elements of the frequency doubler onto a single chip, thereby reducing chip size and manufacturing cost. However, because of the relatively large size of the power splitter used in frequency multiplication technology, integration of the elements onto a single chip requires a relatively large chip area.

Therefore, a need exist for an improved frequency multiplier for doubling an input frequency which may be incorporated onto a single, relatively compact, IC, thus making the multiplier more cost efficient.

### BRIEF DESCRIPTION OF THE DRAWINGS

A more complete understanding of the present invention may be derived by referring to the various exemplary embodiments of the present invention which are described in conjunction with the appended drawings in which like numerals denote like elements, and in which:

FIG. 1 illustrates a block diagram of a prior art frequency doubler system;

FIGS. 2 and 3 illustrate a block diagram of an exemplary embodiment in accordance with the invention;

FIG. 4 is a schematic layout in accordance with an exemplary embodiment of the invention; and

FIG. 5 shows typical frequency responses in accordance with an exemplary embodiment of the invention.

### DETAILED DESCRIPTION OF PREFERRED EMBODIMENTS

In accordance with one aspect of the invention, a frequency multiplier comprises an integrated circuit suitably configured to multiply the frequency of an input signal by a factor of two (herein referred to as “frequency doubler”). Suitably configured, the frequency doubler receives the input signal at two input tuning circuits, where the input tuning circuits may impedance-match the frequency doubler system to the circuitry providing the input signal. In accordance with an exemplary embodiment of the invention, at least one of the tuning circuits may be configured to provide a low-pass frequency response, while the other of the tuning circuits may be configured to provide a high-pass frequency response, such that the low-pass frequency response lags the high-pass frequency response by 180 degrees, and such that both frequency responses will be well balanced.

The balanced signals are then provided to two nonlinear devices for generating balanced signal second harmonics. That is, the low-pass frequency response may be provided to a first non-linear device for generating a second harmonic low-pass signal, and the high pass frequency response may be provided to a second non-linear device for generating a second harmonic of the high-pass frequency signal.

The first and second non-linear devices utilized in the present invention may be configured to have a conduction angle of less than 360 degrees. In deed, the conduction angle of the first and second non-linear devices may be chosen such that conversion gain and rejection of unwanted harmonics is optimized. In addition, the non-linear devices are suitably matched, such that their electrical characteristics are substantially identical. That is, the non-linear transfer function of each non-linear device should be substantially similar.

In yet another embodiment of the invention, the resulting signals from the non-linear devices are provided to an output tuning circuit for combining the signals into one node, which allows the perspective signals to add constructively and destructively. In accordance with another aspect of the invention, the resulting output signal will be strong in the second harmonic and weak in the odd harmonics of the input frequency.

The present invention may be described herein in terms of functional block components as seen in the appended figures. It should be appreciated that such functional blocks may be realized by any number of electrical components configured to perform the specified functions. For example, the invention described herein may employ various circuit topologies, e.g., using integrated circuits or discrete components to implement low pass and high pass frequency responses. In addition, those skilled in the art will appreciate that the invention may be practiced in conjunction with any number of systems where the manipulation of frequency signals is desired, such as receivers or transceivers used in mobile or satellite technology.

To further explain in more detail various aspects of the present invention, exemplary embodiments of the frequency doubler as used to multiply the frequency of an input signal by a factor of two will be provided. However, it should be noted that the following exemplary embodiments are for illustrative purposes, and that the present invention may include various other configurations for increasing an input frequency by multiples of two. In addition, the frequency multiplier can further include components associated with frequency multiplication, such as any required power sources or system control electronics.

Further, those skilled in the art will appreciate that the circuits described herein are merely exemplary and preferred embodiments of the invention and that the particular implementations shown and described herein are various embodiments of the invention and are not intended to otherwise limit the scope of the invention in any way. Indeed, for the sake of brevity, conventional frequency response circuitry, impedance tuning circuitry, transistor biasing technology, and frequency summing technology may not be described in detail, herein. Furthermore, the connecting lines shown in the various figures contained herein, are intended to represent exemplary functional relationships and/or physical couplings between the various elements. It should be noted that many alternative or additional functional relationships or physical connections may be present in a practical frequency doubling circuit.

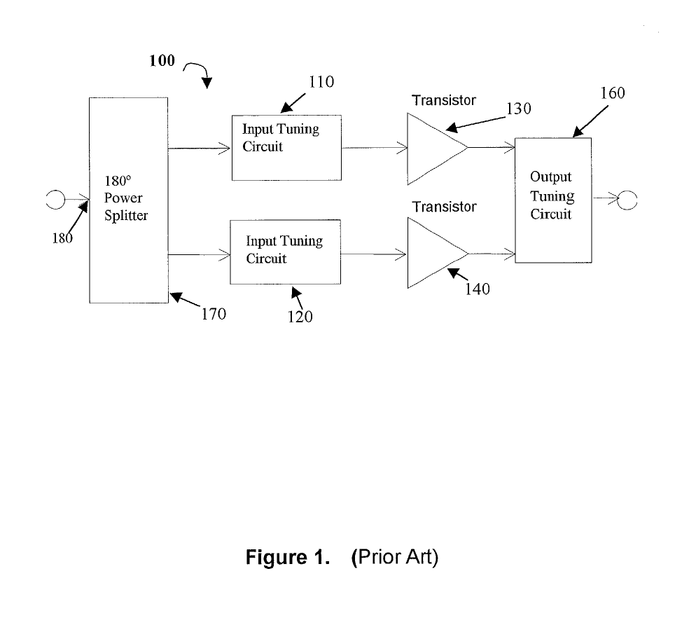

With reference to FIG. 1, a typical prior art design of a push-push multiplier for doubling a frequency signal is illustrated. The prior art frequency doubling system 100 of FIG. 1 comprises a 180 degree power splitter 170, frequency input circuits 110 and 120, transistors 130 and 140, and an output circuit 160.

In practice the 180 degree power splitter 170 is connected to input circuits 110 and 120. Further, input circuits 110 and 120 are connected to transistors 130 and 140, respectively, and transistors 130 and 140 are connected to output circuit 160. The input circuits 110 and 120 of system 100 typically include balanced tuning circuits, transistors 130 and 140 are essentially similar in design, and the output tuning circuit 160 is of any circuit design configured to combine frequency signals into a single node.

During operation, an input signal is provided to 180 degree power splitter 170 at node 180. The power splitter 170 splits the input signal into a first and a second balanced signal, such that the two balanced signals are 180 degrees out-of-phase. The first and second balanced signals are then provided to input circuits 110 and 120, and subsequently provided to transistors 130 and 140, respectively. Transistors 130 and 140 may be biased such that the conduction angle is less than 360 degrees, typically ˜180 degrees, which causes the first signal and the second signal to each approximate a half-rectified sine wave. The two signals are then provided to output circuit 160, where output circuit 160 adds the two signals into a resulting combined signal for delivery to a receiving system for use. The receiving system may be any system wherein a multiple of the frequency of the input signal is desired. One example of such a receiving system is a mixer where it may be necessary to increase the frequency of a local oscillator prior to mixing the local oscillator signal with a RF signal.

One skilled in the art will understand that inherent in the first and second signals rectified by transistors 130 and 140 are various harmonics, with the first harmonic commonly called the fundamental harmonic. For the aforementioned first and second signals, when the signals are combined by the output circuit 160, the signal harmonics of the first signal and the second signal will add either constructively or destructively. Where the harmonics add destructively, a distortion at that harmonic signal can occur. At the harmonic where the signals add constructively, the resulting combined signal will be rich at that particular harmonic. As the adding of frequency signals constructively and destructively is well known in the art, they will not be discussed in detail, herein.

For the frequency doubling system 100, the fundamental and other odd harmonic frequencies of the first and second signals have opposite phase. Consequently, when combined by the output circuit 160, the fundamental and other odd harmonics add destructively, which results in the fundamental and odd harmonics canceling out, or going to zero. The destructive adding of the fundamental harmonics causes the resulting combined signal produced by the output circuit 160 to be low in odd harmonics.

Contrariwise, the second harmonic of the two frequency signals have the same phase. Consequently, when added, the second harmonics of the first and second frequency signals add constructively. That is, the output circuit 160 adds the respective second harmonic frequency signals constructively to produce an output signal that is rich in second harmonic.

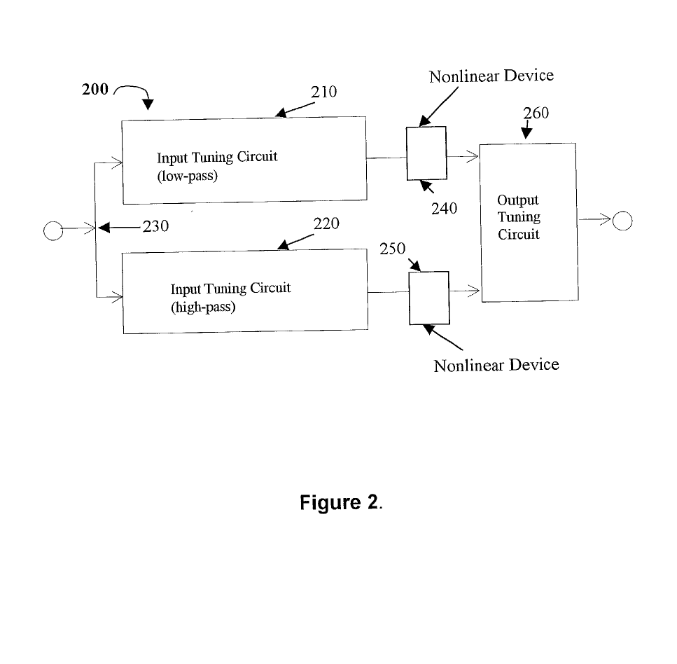

Referring now to FIG. 2, a block diagram of an exemplary frequency doubling system 200 according to the present invention suitably comprises input circuits 210 and 220, nonlinear devices 240 and 250, and an output circuit 260. In accordance with the illustrated embodiment of the invention, frequency doubling system 200 is configured such that a frequency signal may be received at input circuits 210 and 220 via node 230, with a resulting doubled frequency output being provided to an receiving system by output circuit 260.

In accordance with an exemplary embodiment of the invention, input circuit 210 may be any circuit construction or configuration having a low-pass frequency response. Similarly, input circuit 220 may also be any circuit construction or configuration having a high-pass frequency response. Further, the low-pass frequency response of input tuning circuit 210 may be designed to exhibit the same amplitude as the high-pass frequency response of input tuning circuit 220 while maintaining a phase-lag behind the high-pass frequency response of about 180 degrees. Further still, the low-pass and high-pass circuits 210 and 220 along with the output tuning circuit 260 may provide the impedance tuning and signal phasing needed for the second harmonic from the nonlinear device to combine substantially constructively. In addition, the amplitude and phase relationship between the frequency response of input tuning circuit 210 and the frequency response of input tuning circuit 220 may be designed over some desired bandwidth, where the desired bandwidth is determined by the requirements of the receiving circuitry.

Nonlinear devices 240 and 250 may comprise any device or combination of devices suitable for producing a waveform that has a second-harmonic component. In general, to generate the second harmonic, the non-linear device may have a conduction angle of less than 360 degrees.

Further still, output circuit 260 preferably comprises any circuit configuration or construction configured to provide a combined frequency signal output and impedance matching to the receiving circuit (not shown).

In operation, a frequency signal is provided to input circuit 210 and to input circuit 220 via node 230. While input circuit 210 provides a first signal to nonlinear device 240, input circuit 220 provides a second signal to nonlinear device 250. As previously described, the signals provided to the respective nonlinear devices 240 and 250 are phase shifted by 180 degrees relative to each other, which places nonlinear devices 240 and 250 in push-push operation mode.

It is well understood that nonlinear devices with a conduction angle of less that 360 degrees generate a second harmonic frequency. Consequently, when the respective nonlinear device signals are combined by output circuit 260, the frequency of the resulting output signal is substantially equal to the frequency of the input signal multiplied by a factor of two.

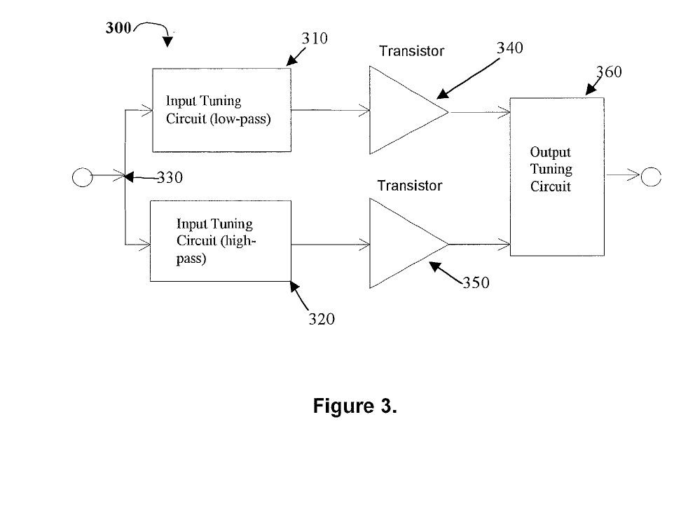

FIG. 3 depicts another block diagram of an exemplary embodiment of the invention. Illustrated in FIG. 3 is a frequency doubling circuit 300 wherein the nonlinear devices comprise transistors 340 and 350. System 300, depicted in FIG. 3, comprises a low-pass input tuning circuit 310, a high-pass input tuning circuit 320, transistors 340 and 350, and output tuning circuit 360.

In accordance with this embodiment of the invention, input tuning circuits 310 and 320 and output tuning circuit 360 can be of any circuit design for processing frequency signals. In particular, input tuning circuits 310 and 320 can be any integrated circuit, discrete circuit, or digital signal processing where input tuning circuit 310 has a low-pass frequency response, and input tuning circuit 320 has a high-pass frequency response. Further, input tuning circuits 310 and 320 may be any circuit where the low-pass transmission amplitude of input tuning circuit 310 is substantially equal to the high-pass transmission amplitude of input tuning circuit 320. In this way, input tuning circuits 310 and 320 are amplitude-balanced.

While conventional low-pass and high-pass frequency response circuitry will not be discussed in detail herein, one skilled in the art will appreciate that such frequency responses circuitry rejects some frequencies within a signal and allows other frequencies to be transmitted. That is, in low-pass frequency response circuitry the frequencies that are transmitted extend from zero to some maximum frequency, while in high-pass frequency response circuitry the frequencies that are transmitted are greater than some minimum frequency.

In accordance with an exemplary embodiment of the present invention, the maximum frequency of the low-pass circuitry is chosen to be substantially similar to the minimum frequency of the high-pass circuitry. Therefore, one skilled in the art will understand that, in general, as input tuning circuit 310 (low-pass) is cutting off, input tuning circuit 320 (high-pass) is cutting on.

Further, input tuning circuits 310 and 320 may additionally be configured to provide impedance tuning to transistors 340 and 350. That is, input tuning circuits 310 and 320 may be designed such that the input circuits 310 and 320 transform the impedance of transistors 340 and 350 to a desired impedance, where the desired impedance is determined by the requirements of the system providing the input signal to node 330.

Transistors 340 and 350 of FIG. 3 may comprise any semiconductor device capable of providing a second-harmonic frequency component, e.g., FETs, Bipolar transistors, MOS transistors, and the like. In addition, to avoid frequency conversion loss, transistors 340 and 350 may be designed to provide gain. Further, in accordance with the illustrated embodiment, transistors 340 and 350 are matched. That is, the transistor construction and design parameters of transistor 340 are matched to, or made substantially similar to, the construction and design parameters of transistor 350.

Further, transistors 340 and 350 are biased such that the conduction angle of each transistor is less than 360 degrees. In an exemplary embodiment of the invention, transistors 340 and 350 are biased with a conduction angle substantially equal to 180 degrees. More particularly, the conduction angle of transistors 340 and 350 is selected to maximize the frequency conversion gain.

Conventional transistor technology is well known in the art. Accordingly, transistor construction and biasing will not be discussed in detail, herein. A number of such prior art elements are described in detail in DIGITAL INTEGRATED CIRCUITS (1st ed. 1996) by Thomas A. DeMassa and Zack Ciccone, the entire contents of which are incorporated herein by reference. One skilled in the art will understand that conventional transistors may require bias injection. Consequently, where bias injection of transistors 340 and 350 is desired, at least one of input tuning circuits 310 and 320, and output circuit 360, may be configured to provide the bias injection. In addition, one skilled in the art will recognize that the described embodiment is not limited to transistor technology. For example, various diodes technologies, such as, for example, Schottky diodes, may be used as the nonlinear device.

Output tuning circuit 360 may be any circuit configured to combine at least two frequency signals into one node. In addition, output circuit 360 may be configured to provide impedance matching to the circuit receiving the combined frequency signal (receiving circuit not shown). That is, the output circuit 360 may be configured to provide the desired output impedance from circuit to circuit and from application to application. In addition, output circuit 360 may be configured to provide filtering of unwanted harmonics resulting from the operation of the nonlinear devices.

In operation, a frequency signal is provided to input tuning circuits 310 and 320 via node 330. While input tuning circuit 310 produces a low-pass frequency response, input tuning circuit 320 produces a high-pass frequency response. The low-pass and high-pass frequency responses are provided to transistors 340 and 350, respectively. Transistors 340 and 350 then provide the frequency responses to output circuit 360. Output circuit 360 then combines the respective transistor 340 and 350 output frequencies into a combined frequency signal.

As noted, in accordance with an exemplary embodiment of the present invention, the low-pass frequency response may be made to lag the high-pass frequency response by about a 180 degree phase difference. Therefore, when the low-pass signal received from transistor 340 is combined with the high-pass signal of transistor 350, the respective signals are combined such that the low-pass signal is about 180 degrees out of phase with the high-pass signal. Moreover, the fundamental component of the signal provided by transistor 340 has opposite phase to the fundamental component of the signal provided by transistor 350. Therefore, when the output circuit 360 combines the respective transistor signals, the fundamental components add destructively in that the signals substantially cancel out or go to zero. Contrariwise, the second harmonic components of the signal provided by the transistor 340 has substantially the same phase position as the second harmonic component of the signal provided by transistor 350. Therefore, the respective second harmonic components of the frequency signals are combined constructively by the output circuit 360. Consequently, the total combined frequency signal provided by the output circuit 360 is rich in second harmonic and has a frequency equal to two times the frequency of the signal received by the frequency doubling system 300.

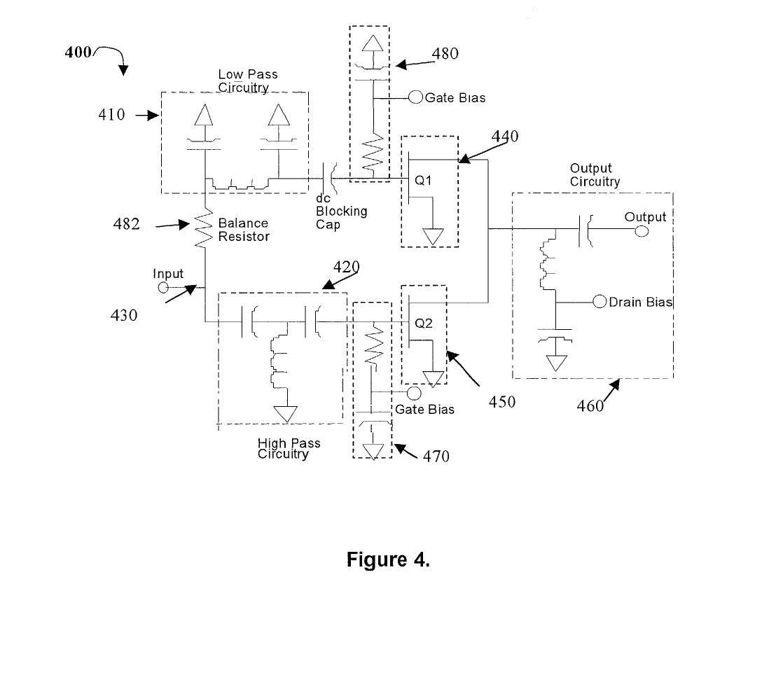

Turning now to FIG. 4, an exemplary circuit realization of a frequency doubling system 300 in accordance with one embodiment of the invention is illustrated. That is, one of ordinary skill in the art will understand that frequency doubling system 300 may be configured using the schematic diagram depicted in FIG. 4. More particularly, the elements of the system of FIG. 3 may be realized using the schematic illustrated in FIG. 4, where the frequency doubling system 400 of FIG. 4 includes a low-pass input tuning circuit 410, a high-pass input tuning circuit 420, transistors 440 and 450, and an output circuit 460. In addition, frequency doubling system 400 further includes gate biasing circuits 470 and 480, and a balancing resistor 482.

Gate biasing circuits 470 and 480 provide gate bias to transistors 440 and 450. In this embodiment of the invention, transistor 440 is connected to its own gate bias circuit 480 and transistor 450 is connected to its own gate bias circuit 470. This allows the gate bias voltage of transistor 440 to be different than the gate bias voltage of transistor 440 which can be useful in improving conversion gain or improving the rejection of unwanted harmonics. The balancing resistor 482 helps ensure that the signals provided by transistors 440 and 450 are amplitude balanced.

While FIG. 4 shows an exemplary embodiment of the invention using passive elements, it should be understood that the description of the invention is not to be so limited. For example, the elements of FIG. 4 may be realized using distributed elements, discrete components or integrated circuits and any combination thereof. In addition, one skilled in the art will recognize that the components of the circuitry shown in FIG. 4 may be integrated onto a single chip or integrated with related circuitry onto a single chip. Further, in yet another embodiment of the frequency doubling system 400, the gate of transistor 440 is connected to the gate of transistor 450, and a DC voltage is provided to the point of connection of the connected gates. In this embodiment, a suitable DC current does not overly degrade the amplitude of the desired AC signals and would permit gate bias to applied to only one side.

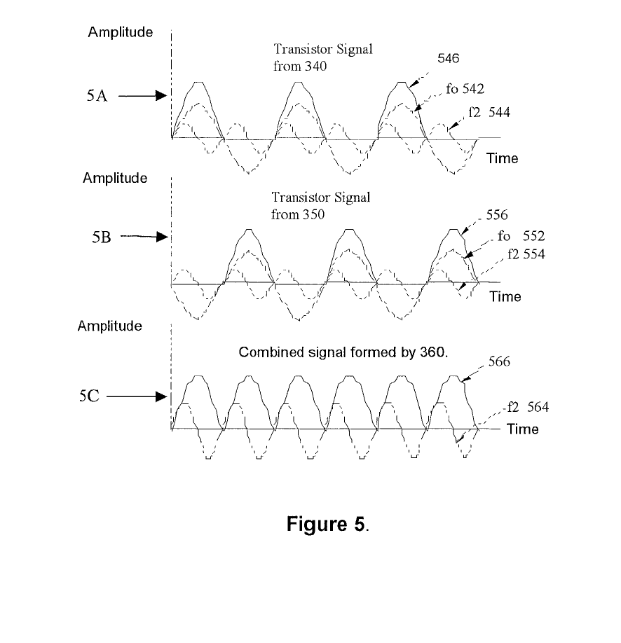

Turning now to FIG. 5, an exemplary frequency response in accordance with one embodiment of the invention is illustrated. While FIG. 5 illustrates typical frequency responses according to the invention, one skilled in the art will recognize that the depictions shown are merely illustrative and, therefore, are not intended to limit the scope of the invention. That is, FIG. 5 shows a typical graph of the frequency output of transistors 340 and 350 of FIG. 3, and the combined frequency signal as provided by output circuit 360. In particular, graph 5A depicts the low-pass frequency signal fundamental component 542, the low-pass frequency signal second harmonic component 544, and the half-rectified frequency signal output 546 as transmitted by transistor 340 of FIG. 3. Similarly, graph 5B depicts the high-pass frequency signal fundamental component 552, the high-pass frequency signal second harmonic component 554, and the half-rectified frequency signal output 556 as transmitted by transistor 350 of FIG. 3. In addition, graph 5C, of FIG. 5 depicts the combined signal formed by output circuit 360 of FIG. 3. In particular, what is illustrated is the second harmonic component 564 and the combined frequency signal 566 of frequency doubling system 300 of FIG. 3. More particularly, graph 5C of FIG. 5, illustrates an exemplary output signal where the output circuit 360 of FIG. 3 has combined the signals illustrated in FIGS. 5A and 5B of figure

As shown in FIG. 5, the fundamental component 542 of the low pass frequency signal depicted in graph 5A and the fundamental component 552 of the high pass frequency signal depicted in graph 5B are about 180 degrees out of phase. Consequently, when fundamental components 542 and 552 are combined by output circuit 360 of FIG. 3, the destructive interference of the fundamental components causes the resulting combined fundamental signal to substantially cancel, or go to about zero.

The second harmonic components 544 and 554 of graph 5A and 5B respectively are depicted in phase. As shown in graph 5C, when second harmonics 544 and 554 are combined, the signals add constructively. Therefore, the output waveform illustrated in graph 5C has a very strong second harmonic component 564.

With continued reference to FIGS. 3 and 5, the output signals of transistors 340 and 350 is shown. In particular, the output signals of transistors 340 and 350 are shown as half-rectified frequency signals 546 and 556 of FIG. 5, respectively. As noted, the signal provided by input tuning circuit 310 of FIG. 3 is about 180 degrees out of phase with the signal provided by input tuning circuit 320. Therefore, the signals provided by transistor 340 and transistor 350 will also be substantially 180 degrees out of phase. Moreover, as shown in graph 5C, when half-rectified signals 546 and 556 are combined into a combined frequency signal as shown by signal 566 of graph 5C the frequency of the resulting combined signal 566 is substantially equal to the frequency of the signal input into frequency doubling system 300, multiplied by a factor of two. Therefore, as has been described herein, the exemplary embodiments of the present invention illustrated by systems 200, 300, and 400 each function as a frequency doublers.

Although the subject invention is described herein in conjunction with the appended figures, it will be appreciated that the invention is not so limited to the specific forms shown. Various modifications in the selection and arrangement of the components or circuits may be implemented without departing from the scope of the invention. For example, although the preferred embodiment is set forth in which various passive and discrete elements are depicted, it will be appreciated that the invention is not to be so limited. It is to be understood by those skilled in the art of this invention, that various modification come within the scope of the invention as set forth in the specification and the appended claims.

What is claimed is:

1. A frequency doubler comprising:
a) a first input tuning circuit, said first input tuning circuit configured to provide a low-pass frequency response;
b) a first non-linear circuit device electrically connected to said first input tuning circuit;
c) a second input tuning circuit, said second input tuning circuit configured to provide a high-pass frequency response;
d) a second non-linear circuit device electrically connected to said second input tuning circuit; and
e) an output tuning circuit electrically connected to said first non-linear circuit device and said second non-linear circuit device.

2. A frequency doubler according to claim 1, wherein said first input tuning circuit and said second input tuning circuit are substantially amplitude balanced.

3. A frequency doubler according to claim 1, wherein said first input tuning circuit and said second input tuning circuit are phase balanced for push-push operation..

4. A frequency doubler according to claim 1, wherein said first input tuning circuit transforms the impedance of said first non-linear circuit device to a predetermined impedance.

5. A frequency doubler according to claim 1, wherein said second input tuning circuit transforms the impedance of said second non-linear circuit device to said predetermined impedance.

6. A frequency doubler according to claim 1, wherein said first input tuning circuit comprises a low-pass circuit maximum frequency.

7. A frequency doubler according to claim 1, wherein said second input tuning circuit comprises a high-pass circuit minimum frequency.

8. A frequency doubler according to claim 1, wherein the maximum frequency of said first input tuning circuit is substantially similar to said minimum frequency of said second input tuning circuit.

9. A frequency doubler according to claim 1, wherein said first non-linear circuit device and said second non-linear circuit device have a conduction angle less than 360 degrees, wherein said conduction angle is selected to achieve a desired frequency conversion gain and rejection of unwanted harmonics.

10. A frequency doubler according to claim 1, wherein said output tuning circuit provides impedance matching.

11. A frequency doubler according to claim 1, wherein said output tuning circuit provides a bias injection to said first non-linear circuit device and said second non-linear circuit device.

12. A frequency doubler according to claim 1, wherein first input tuning circuit provides a bias injection to said first non-linear circuit device.

13. A frequency doubler according to claim 1, wherein said second input tuning circuit provides a bias injection to said second non-linear circuit device.

14. A frequency doubler according to claim 1, wherein said output circuit provides a frequency substantially equal to two times the frequency of the fundamental component of a frequency input into said frequency doubler.

15. A frequency doubler according to claim 1, wherein said frequency doubler comprises a push-push circuit arrangement.

16. A frequency doubling circuit comprising:
a) a first circuit configured to provide a first half-rectified frequency signal, said first circuit including a low-pass topology;
b) a second circuit configured to provide a second half rectified frequency signal substantially 180 degrees out of phase with said first half-rectified frequency signal, said second circuit including a high-pass topology; and
c) an output circuit electrically connected to said first circuit and said second circuit, said output circuit combining said first half-rectified frequency signal and said second half-rectified frequency signal.

17. A frequency doubling circuit according to claim 16, wherein said output circuit provides a predetermined impedance matching.

18. A frequency doubling circuit according to claim 16, wherein said first circuit and said second circuit are amplitude balanced.

19. A frequency doubling circuit according to claim 16, wherein said first circuit and said second circuit are phase balanced for push-push operation.

20. A frequency doubler according to claim 16, wherein said first circuit comprises a low-pass circuit maximum frequency.

21. A frequency doubler according to claim 16, wherein said second circuit comprises a high-pass circuit maximum frequency.

22. A frequency doubling circuit according to claim 16, wherein said first circuit maximum frequency is substantially similar to said second circuit minimum frequency.

23. A method of doubling a frequency comprising:
receiving a frequency signal at a first input circuit configured to provide a low-pass frequency signal to a first non-linear device, said first non-linear device configured to provide a first non-linear device signal to an output circuit;
receiving said frequency signal at a second input circuit configured to provide a high-pass frequency signal to a second non-linear device, said second non-linear device configured to provide a second non-linear signal to said output circuit, said high-pass frequency signal being substantially 180 degrees out of phase with said low pass frequency signal;
providing said low-pass frequency signal to said first non-linear device, and providing said high pass frequency signal to said second non-linear device;
providing said first non-linear device signal and said second non-linear device signal to said output circuit, said output circuit configured to combine said first transistor signal and said second transistor signal into a combined frequency signal;
transforming the impedance of the first non-linear device and the second non-linear device to a predetermined impedance; and
combining said first non-linear device signal and said second non-linear device signal into a single electrical node.
